(19) United States
(12) Patent Application Publication
(10) Pub. No.: US 2005/0166957 A1
(43) Pub. Date: Aug. 4, 2005

(54) Photoelectric conversion device

(76) Inventors: Tsutomu Imoto, Kanagawa (JP); Masashi Enomoto, Tokyo (JP)

Correspondence Address: WOLF GREENFIELD & SACKS, PC;FEDERAL RESERVE PLAZA, 600 ATLANTIC AVENUE, BOSTON, MA, 02210-2211, US

(21) Appl. No.: 10/515,366

(22) PCT Filed: May 23, 2003
(86) PCT No.: PCT/JP03/06471

(30) Foreign Application Priority Data
May 27, 2002 (JP) 2002-151722

(51) Int. Cl. H01L 31/00

(52) U.S. Cl. 136/263; 136/252; 136/256; 136/249

(57) ABSTRACT

A photoelectric transducer having a relatively simple structure and capable of reducing the loss of light energy of incident light and conductor loss due to electrical resistance. A photoelectric transducer 16A includes a conductive layer 2; a electrolytic layer 3 that is in contact with the conductive layer 2; a charge separating layer 4; a transparent conductive layer 5 and a metal lines 7, which are in contact with the charge separating layer 4; and convex lenses 8 converging incident light 15 on openings 20 provided between the metal lines 7, the incident light 15 being converged on the charge separating layer 4 by the convex lenses 8. Electrons generated by photoelectric conversion move to the exterior through an external circuit 17 having a low resistivity.

### TECHNICAL FIELD

The present invention relates to a photoelectric transducer suitable for a dye-sensitized photoelectric transducer such as a photoelectrochemical solar cell (hereinafter, referred to as “wet solar cell”).

### BACKGROUND ART

Various dye-sensitized photoelectric transducers such as wet solar cells have been known. For example, FIG. 10 is a cross-sectional view showing an example of the basic structure of a photoelectric transducer 66A.

This photoelectric transducer 66A includes the following constituents: A substrate 51 is composed of glass or a plastic, both of which have satisfactory mechanical strength. A conductive layer 52 composed of indium tin oxide (ITO) is provided on the substrate 51 by vapor deposition. An electrolytic layer 53 is provided on the conductive layer 52 and includes an electrolytic solution containing an iodine-iodide electrolyte and a mixed solvent containing acetonitrile and ethylene carbonate.

A first charge separating layer 54 is provided on the electrolytic layer 53 and is composed of sintered ultra-fine titanium oxide (TiO₂) particles, which have a diameter of 10 nm to 30 nm, adsorbing a ruthenium complex, i.e., RuL₂(NCS)₂ (where L: 4,4′-dicarboxy-2,2′-bipyridine) functioning as sensitizing dye. A transparent conductive layer 55 having a thickness of 0.3 μm is provided on the first charge separating layer 54 and is composed of ITO formed by vapor deposition. A transparent substrate 56 is provided on the transparent conductive layer 55 in order to hold the transparent conductive layer 55 and the first charge separating layer 54, and the transparent substrate 56 is composed of glass.

The conductive layer 52 is connected to the transparent conductive layer 55 via an external circuit 67. Electrons move from the transparent conductive layer 55 functioning as an anode to the conductive layer 52 functioning as a cathode through the external circuit 67, which has an external load 71. In this process, the external load 71 can use electrical energy.

In the photoelectric transducer 66A having the above-described structure, incident light 65 from the exterior passing through the transparent substrate 56 and the transparent conductive layer 55 is absorbed by the sensitizing dye in the first charge separating layer 54. As a result, electron-hole pairs are generated by photoelectric conversion.

Next, the generated electrons flow into the transparent conductive layer 55 through the ultra-fine TiO₂ particles in the first charge separating layer 54, and then move into the conductive layer 52 via the external circuit 67 having the external load 71 to reduce iodine to iodide ions. The resulting iodide ions provide electrons for holes on the sensitizing dye and are oxidized themselves.

FIG. 11 is a cross-sectional view showing another example of the basic structure of a general dye-sensitized photoelectric transducer 66B.

This structure is the same as in FIG. 10, but the first charge separating layer 54 is provided on a surface of the conductive layer 52. Incident light 65 passing through the transparent substrate 56, the transparent conductive layer 55, and the electrolytic layer 53 is absorbed by the sensitizing dye in the first charge separating layer 54. Generated electrons behave in the same way as in the photoelectric transducer 66A shown in FIG. 10, but the generated electrons move from the conductive layer 52 functioning as an anode to the transparent conductive layer 55 functioning as a cathode through the external circuit 67.

However, both photoelectric transducers shown in FIGS. 10 and 11 mainly have the following two problems: Since the transparent conductive layer 55 has a relatively-high electrical resistance, when electrons pass through this layer, conductor loss (loss due to Joule heat generated by the electrical resistance of the conductor) occurs to reduce photoelectric conversion efficiency. Since the incident light 65 is partially absorbed by the transparent conductive layer 55, part of the energy of the incident light 65 cannot contribute to photoelectric conversion.

Since there is a trade-off between the two problems, the two problems cannot be simultaneously solved. That is, an increase in the thickness of the transparent conductive layer 55 reduces its electrical resistance to decrease the conductor loss, but increases the absorption of the incident light 65 to increase the loss of light energy.

Among these problems, to reduce the electrical resistance, photoelectric transducers shown in FIGS. 12 and 13 are disclosed.

In a photoelectric transducer 66C shown in FIG. 12, to improve the conductive performance of the transparent conductive layer 55, low-resistance metal lines 57 composed of, for example, aluminum or copper are spaced at predetermined intervals under a surface of the transparent conductive layer 55, in addition to the structure shown in FIG. 10. Electrons generated by photoelectric conversion in the first charge separating layer 54 are readily collected in the metal lines 57 directly or through the transparent conductive layer 55.

In such a structure, even when some of the electrons generated by photoelectric conversion in the first charge separating layer 54 pass through the transparent conductive layer 55, the electrons can relatively readily flow into the low-resistance metal lines 57. In some positions where the electrons are generated, electrons can directly move into the metal lines 57 without passing through the transparent conductive layer 55. Hence, the number of electrons passing through the high-resistance transparent conductive layer 55 is reduced. Consequently, electrons can move to the exterior through the low-resistance metal lines 57, thus reducing the electrical resistance.

In a photoelectric transducer 66D shown in FIG. 13, the metal lines 57 having a grid pattern are disposed in the electrolytic layer 53. The first charge separating layer 54 and a second charge separating layer 60 are disposed on both sides of the electrolytic layer 53. The conductive layer 52 and the transparent conductive layer 55, which function as anodes, are connected in parallel. Electrons generated by photoelectric conversion move into the metal lines 57 functioning as cathodes through the conductive layer 52 and the transparent conductive layer 55. Consequently, the electric resistance is further reduced.

In the photoelectric transducer 66C shown in FIG. 12, since the area ratio of the first charge separating layer 54 to the metal lines 57 is about 1:1, the area of an opening 70, which transmits incident light to the first charge separating layer 54, between metal lines 57 is reduced. That is, the opening ratio is low. In other words, since the incident light 65 is partially reflected by the metal lines 57, a portion of the incident light 65 cannot reach the first charge separating layer 54, thus resulting in loss of light energy.

This loss of light energy is improved by reducing the area ratio of the metal lines 57 to the first charge separating layer 54 that receives the incident light. However, a decrease in the width and/or the cross-sectional area of the metal lines 57 increases the electrical resistance and reduces the conductive performance of the transparent conductive layer 55. Since there is a trade-off between these problems, these problems cannot be simultaneously solved.

In the photoelectric transducer 66D shown in FIG. 13, the incident light 65 can be subjected to photoelectric conversion in both the first charge separating layer 54 and the second charge separating layer 60. In other words, light passing through the opening 70 between the metal lines 57 can be subjected to photoelectric conversion, while light produced by reflecting the incident light 65 at the metal lines 57 can reenter the second charge separating layer 60. Hence, this structure can suppress the loss of light energy to some extent. However, since, electrons generated by photoelectric conversion in the first charge separating layer 54 and the second charge separating layer 60 pass through the conductive layer 52 and the transparent conductive layer 55, respectively, conductor loss in the same way as in the above description occurs. Furthermore, this complicated structure increases the manufacturing costs.

The loss of light energy due to light absorption in the transparent conductive layer 55 is unavoidable in these structures shown in both FIGS. 12 and 13.

In view of the above problems in the conventional art, the present invention has as an object to provide a photoelectric transducer that reduces conductor loss due to electrical resistance and the loss of light energy due to the absorption or reflection of incident light, and that has a relatively simple structure.

### DISCLOSURE OF INVENTION

That is, the present invention provides a photoelectric transducer (for example, a photoelectric transducer 16A suitable for a wet solar cell described below) including a first electrode (for example, a conductive layer 2 described below); a charge-separating means (for example, a charge separating layer 4 and an electrolytic layer 3, described below) in contact with the first electrode; a second electrode (for example, metal lines 7 and a transparent conductive layer 5, described below) in contact with the charge-separating means; and a light-guiding means (for example, a convex lens 8, which is an on-chip lens, described below) guiding incident light to a transparent portion (for example, an opening 20 described below) provided in a low-resistance region (for example, the metal lines 7 described below) of the second electrode, the light-guiding means guiding the incident light to the charge-separating means.

According to the present invention, by providing the low-resistance region, i.e., high-conductivity region in the second electrode that is in contact with the charge-separating means, electrons generated by photoelectric conversion in the charge-separating means are collected in the low-resistance region. Since the collected electrons move into an external circuit through the low-resistance region, the above-described conductor loss is reduced. In this way, a low-loss path for the transfer of electrons (improvement of mobility) can be ensured.

Since the incident light is led to the transparent portion provided in the low-resistance region by the light-guiding means and then is led to the charge-separating means, the path of the incident light can be controlled such that at least the major portion of the incident light is incident on the charge-separating means. The loss of incident light, i.e., the loss of light energy caused by the reflection of the incident light from a region other than the transparent portion can be blocked; therefore, the incident light can efficiently enter the charge-separating means. Even when a light-absorbing layer such as a transparent conductive layer is present in the second electrode, the light-guiding means reduces the amount of light that is incident on the light absorbing layer, thus reducing the amount of light absorption. Since such a path of incident light can be achieved even when the transparent portion is reduced in width, the area of the low-resistance region can be enlarged to such a degree that the low-resistance region does not interfere with the path of incident light. As a result, generated electrons readily flow into the low-resistance region, and the conductivity of the electrode is increased. Consequently, both the conductor loss and the loss of light energy can be further suppressed.

The relatively simple structure formed only by providing the light-guiding means in addition to the first electrode, the second electrode, and the charge-separating means can reduce the conductor loss and the loss of light energy.

### BRIEF DESCRIPTION OF THE DRAWINGS

FIG. 1 is a schematic cross-sectional view of a photoelectric transducer according to a first embodiment of the present invention.

FIG. 2 is a plan view of the photoelectric transducer.

FIG. 3 is a schematic cross-sectional view of a photoelectric transducer according to a second embodiment of the present invention.

FIG. 4 is a schematic cross-sectional view of a photoelectric transducer according to a third embodiment of the present invention.

FIG. 5 is a schematic cross-sectional view of another photoelectric transducer according to the third embodiment of the present invention.

FIG. 6 is a schematic cross-sectional view of a photoelectric transducer according to a fourth embodiment of the present invention.

FIG. 7 is a schematic cross-sectional view of a photoelectric transducer according to a fifth embodiment of the present invention.

FIG. 8 is a schematic cross-sectional view of a photoelectric transducer according to a sixth embodiment of the present invention.

FIG. 9 is a schematic cross-sectional view of a photoelectric transducer according to a seventh embodiment of the present invention.

FIG. 10 is a schematic cross-sectional view of a conventional photoelectric transducer.

FIG. 11 is a schematic cross-sectional view of another conventional photoelectric transducer.

FIG. 12 is a schematic cross-sectional view of another conventional photoelectric transducer.

FIG. 13 is a schematic cross-sectional view of yet another conventional photoelectric transducer.

### BEST MODE FOR CARRYING OUT THE INVENTION

A photoelectric transducer according to the present invention is preferably constructed as a wet solar cell. That is, a charge-separating means is preferably composed of an electrolytic layer containing an iodine-iodide electrolyte and a charge separating layer that is in contact with the electrolytic layer. Hereinafter, a photoelectric transducer having such a charge-separating means is referred to as “wet photoelectric transducer”. In this case, the charge separating layer is preferably composed of a semiconductor sublayer, for example, a TiO₂ sublayer containing a sensitizing dye or a TiO₂ sublayer on which a sensitizing dye adheres.

In addition, the charge-separating means may include a junction including p-type and n-type semiconductors (a p-n junction semiconductor or a p-i-n junction semiconductor). A photoelectric transducer having such a charge-separating means (hereinafter, referred to as “dry photoelectric transducer”) may be used.

In view of its ability to guide and converge incident light and to reduce the size, the light-guiding means is preferably a convex or concave on-chip lens provided above the transparent portion. The on-chip lens may be composed of an organic material that transmits light, for example, a transparent resin processed on a transparent substrate by photolithography.

The light-guiding means may be composed of a lens array (for example, a glass lens array integrally formed on a transparent substrate) disposed above the transparent portion.

To adjust the position of the on-chip lens to the transparent portion of the second electrode, a boundary region between adjoining on-chip lenses is preferably disposed above the second electrode.

To efficiently transfer electrons generated in the charge-separating means, the second electrode preferably includes metal lines, which are composed of, for example, platinum (Pt) or copper (Cu), having a predetermined pattern and an transparent conductive layer, which is composed of, for example, ITO, being in contact with the metal lines, wherein the metal lines and/or the transparent conductive layer is in contact with the charge-separating means.

In this case, the metal lines or the transparent conductive layer may be disposed adjacent to the charge-separating means.

The second electrode preferably includes metal lines, which are composed of, for example, Pt or Cu, having a predetermined pattern, the metal lines being in contact with the charge-separating means.

In this case, the metal lines may be in contact with the charge separating layer or the electrolytic layer.

Preferred embodiments of the present invention will now be described with reference to the drawings.

### First Embodiment

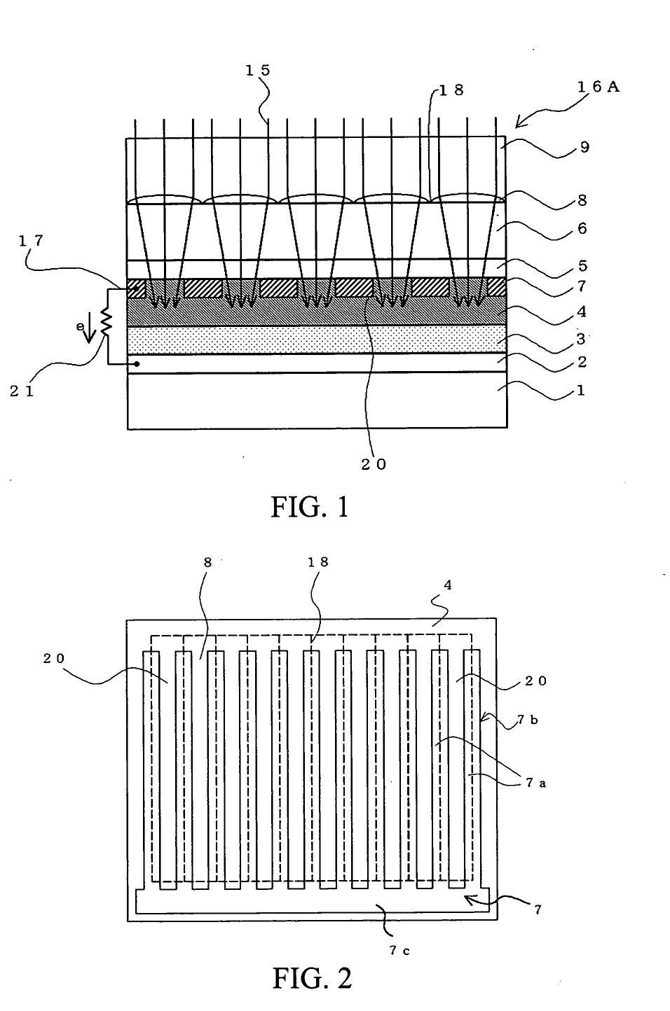

As shown in FIG. 1, in a photoelectric transducer 16A functioning as a wet solar cell according to this embodiment, a conductive layer 2 that is composed of, for example, ITO, gold, or platinum is formed on a substrate 1 composed of glass or a plastic by, for example, vacuum deposition, sputtering, chemical vapor deposition (CVD), or a sol-gel method.

An electrolytic layer 3 provided on the conductive layer 2 is composed of, for example, an electrolytic solution containing an iodine-iodide electrolyte and a mixed solvent containing acetonitrile and ethylene carbonate. The electrolytic solution contains, for example, 0.6 mol/L of tetrapropylammonium iodide and 5×10² mol/L of iodine.

A charge separating layer 4 includes a semiconductor sublayer such as an ultrafine TiO₂ particle sublayer adsorbing a ruthenium complex, i.e., RuL₂(NCS)₂ (where L: 4,4′-dicarboxy-2,2′-bipyridine) functioning as sensitizing dye. This ultrafine particle sublayer is composed of sintered ultrafine TiO₂ particles each having a diameter of 10 nm to 30 nm. The ultrafine particle sublayer may be composed of the sintered TiO₂ layer impregnated with the sensitizing dye or may be composed of the TiO₂ semiconductor layer on which the sensitizing dye adheres.

The charge separating layer 4 may be composed of not only a TiO₂ layer that is composed of ultra-fine particles, but also any other materials, for example, potassium tantalate (KTaO₃), zinc oxide (ZnO), or tin dioxide (SnO₂) The charge separating layer 4 can be formed by sputtering or a sol-gel method.

A transparent conductive layer 5 provided on the charge separating layer 4 is composed of tin oxide doped with antimony or fluorine or an ITO thin film having a thickness of, for example, 0.3 μm formed by vacuum deposition, sputtering, chemical vapor deposition (CVD), coating, or a sol-gel method.

Metal lines 7 are composed of low-resistance lines produced by forming, for example, a Pt film having a thickness of, for example, 300 nm by, for example, vacuum deposition and then patterning the resulting Pt film by, for example, a lift-off method.

The transparent conductive layer 5, the metal lines 7, and the charge separating layer 4 are provided on a transparent substrate 6, in that order. As shown in FIG. 2, a comb-shaped pattern having openings 20 that transmit incident light 15 is provided.

Convex lenses 8 for converging the incident light 15 on the openings 20 is composed of, for example, on-chip lenses that are provided on the transparent substrate 6 and that are composed of an organic material such as a transparent resin which transmits light, or a lens array stacked and fixed on the transparent substrate 6. Materials and methods for producing such lenses are known. For example, an integrally formed lens array or a planar microlens array may be used.

A lens protecting layer 9 that is intended to protect the convex lenses 8 is composed of a material having a smaller refractive index than that of the convex lens 8 in order to prevent the total reflection of the incident light 15 and in order to enhance the ability of the convex lens 8 to converge the incident light 15. The lens protecting layer 9 may be provided, if necessary.

The conductive layer 2 and the metal lines 7 are connected to each other via an external circuit 17; hence, electrons generated by photoelectric conversion in the charge separating layer 4 can move from the metal lines 7 (anode) to the conductive layer 2 (cathode) through the external load 21.

According to the photoelectric transducer 16A described above, the incident light 15 from outside comes through the lens protecting layer 9 and is then incident on the convex lenses 8. After the light passes through the transparent substrate 6 and transparent conductive layer 5 while converging due to the effect of the lenses, the light converges on the openings 20 between adjoining metal lines 7. Therefore, the light can efficiently enter the charge separating layer 4 without being reflected from the metal lines 7.

The incident light 15 that enters the charge separating layer 4 is absorbed in the sensitizing dye in the charge separating layer 4, and then electron-hole pairs are generated by photoelectric conversion.

The generated electrons move into the transparent conductive layer 5 and then flow into the metal lines 7, or they directly flow into the metal lines 7 through the TiO₂ ultra-fine particles in the charge separating layer 4. Since the metal lines 7 have high electrical conductivity, i.e., low electrical resistivity, the electrons readily move into the external circuit 17 and then flow into the conductive layer 2 via the external load 21. Iodine in the electrolytic layer 3 is reduced to generate iodide ions. The resulting iodide ions provide electrons for holes on the sensitizing dye and are oxidized themselves.

In plan view of the photoelectric transducer 16A shown in FIG. 2, the metal lines 7 have a structure in which one end of a comb-shaped electrode 7b, which has branched electrodes 7a, is connected at a connecting portion 7c that is connected to the external circuit 17.

Electrons generated by incident light converging on the openings 20 between the branched electrodes 7a in the charge separating layer 4 readily flow into the nearest branched electrode 7a and then smoothly move from the branched electrodes 7a to the exterior via the connecting portion 7c. In this case, the travel distance of electrons which move to the branched electrode 7a through the transparent conductive layer 5 having relatively high resistance is substantially about half the distance between the branched electrodes 7a (that is, the width of the opening 20); hence, the conductor loss caused by the passage of the electrons through the transparent conductive layer 5 is significantly reduced.

The convex lenses 8 are disposed along the comb-shaped electrode 7b so that convex-lens edges 18 are disposed above the branched electrodes 7a of the comb-shaped electrode 7b. As shown in FIG. 1, since the incident light 15 efficiently enters the charge separating layer 4 through the openings 20 between the branched electrodes 7a (metal lines 7) while being converged by the convex lens 8, substantially no reflection from the branched electrodes 7a occurs. Therefore, the loss of light energy is minimized.

The conditions of, for example, positions, sizes, shapes, materials, and the numbers of the convex lenses 8 and the metal lines 7 are not limited to the above, but may be changed as desired.

As described above, according to this embodiment, since the metal lines 7 having a higher conductivity than that of the transparent conductive layer 5 are in contact with the charge separating layer 4, electrons generated by photoelectric conversion in the charge separating layer 4 readily flow into the metal lines 7. The electrons can move to the exterior through the metal lines 7. That is, since a low-loss path for the transfer of electrons is ensured, the electrons can smoothly move into the conductive layer 2. Consequently, the conductor loss due to electrical resistance can be significantly reduced.

In addition, since the incident light 15 is efficiently converged to the charge separating layer 4 by the convex lenses 8, in other words, since at least the major portion of the incident light 15 can efficiently enter the charge separating layer 4 through the openings 20 between the metal lines 7, the loss of light energy caused by the reflection of the incident light 15 from the metal lines 7 can be minimized. Therefore, the photoelectric conversion efficiency can be significantly improved.

Furthermore, when the incident light 15 is incident on the transparent conductive layer 5, the light absorption caused by the transparent conductive layer 5 can be reduced because of the reduced incident area (amount of incident light) due to the convex lenses 8.

In addition, since the incident light 15 is converged by the convex lenses 8, even when the area of the opening 20 is reduced, the incident light 15 can efficiently enter the charge separating layer 4. Hence, the area or width of the metal lines 7 can be enlarged to such a degree that the metal lines 7. do not interfere with the incident light 15 and with the function of the charge separating layer 4. As a result, electrons flow into the metal lines 7 more easily. The electrical resistance of the metal lines 7 can be reduced, i.e., the electrical conductivity can be increased. Therefore, both the conductor loss and the energy loss can be further reduced.

In this case, the width ratio of the openings 20 to the metal lines 7 is, for example, 0.9:1. That is, the width of the metal lines 7 can be greater than that of a conventional structure. Furthermore, an increase in the thickness of the metal lines 7 can further reduce their electrical resistance.

The photoelectric transducer 16A having a relatively simple structure can be formed simply by providing the convex lenses 8 in addition to the conductive layer 2, the electrolytic layer 3, the charge separating layer 4, the transparent conductive layer 5, and the metal lines 7. This structure can reduce the conductor loss and the loss of light energy.

### Second Embodiment

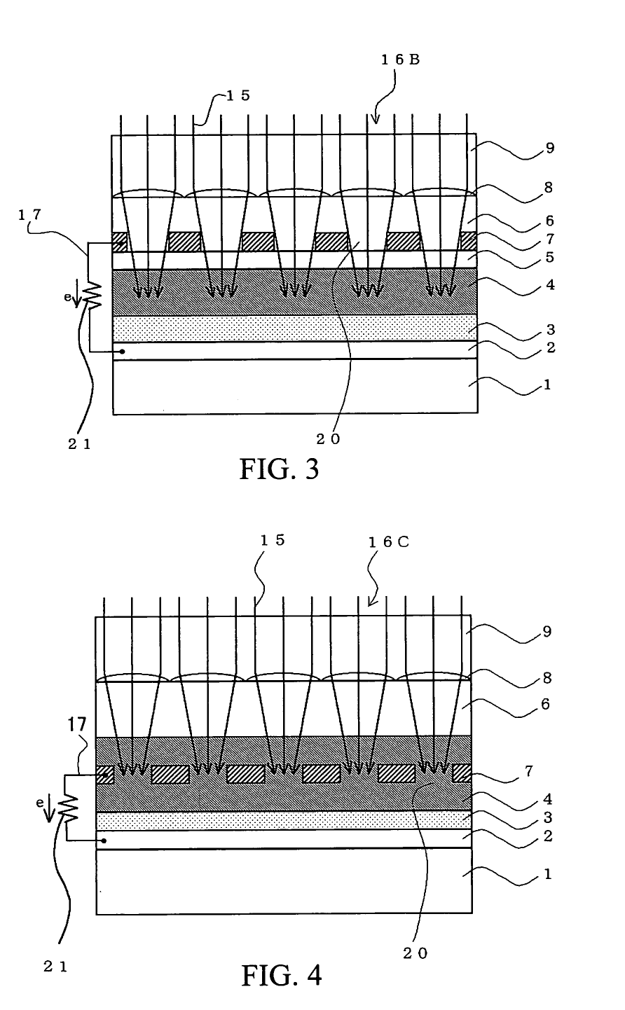

As shown in FIG. 3, the photoelectric transducer 16B of this embodiment is as in the first embodiment, but the metal lines 7 are provided not within the charge separating layer 4 but on the transparent conductive layer 5.

According to this embodiment, the incident light 15 converging on the openings 20 between the metal lines 7 passes through the transparent conductive layer 5 and then efficiently enters the charge separating layer 4. Hence, electrons generated in the charge separating layer 4 can readily pass through the transparent conductive layer 5 and flow into the metal lines 7.

This embodiment can also achieve the same effects as in the first embodiment described above.

### Third Embodiment

As shown in FIG. 4, a photoelectric transducer 16C of this embodiment is as in the first embodiment, but the transparent conductive layer 5 is omitted and the metal lines 7 is disposed at the middle along the thickness direction in the charge separating layer 4.

In this embodiment, light energy is not absorbed in the transparent conductive layer 5 by virtue of the absence of the transparent conductive layer 5. Hence, almost all incident light 15 can enter the charge separating layer 4.

Since the metal lines 7 are disposed at the inside of the charge separating layer 4, electrons generated in the charge separating layer 4 directly flow into the metal lines 7; hence, the conductor loss caused by the passage of the electrons through the transparent conductive layer 5 does not occur. In case where incident light is partially reflected by the metal lines 7, only a minimal amount of light is reflected. Furthermore, since photocarriers are generated by the reflected light, the reflection contributes to improvement of the efficiency of the photoelectric conversion.

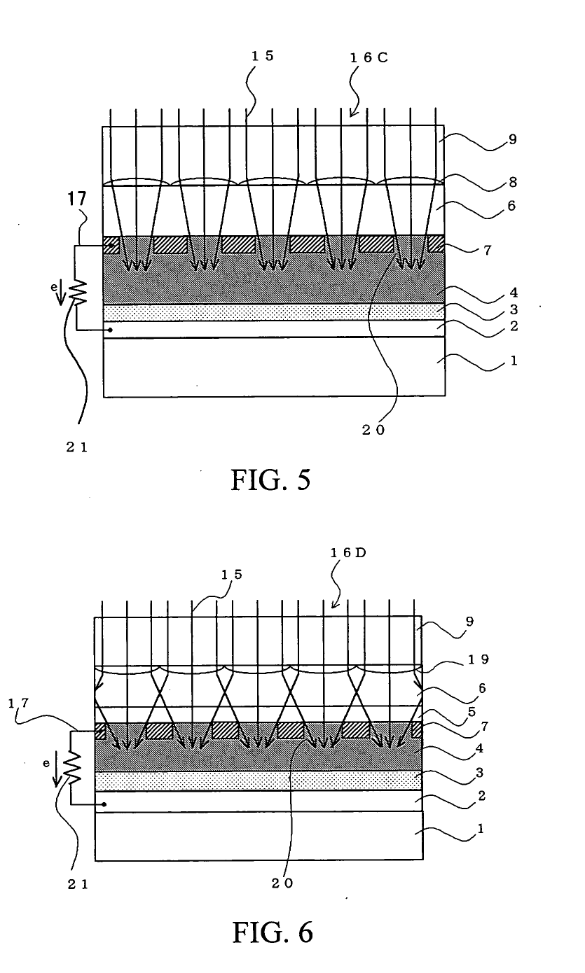

For example, the position of the metal lines 7 in the charge separating layer 4 may be set as desired. For example, as shown in FIG. 5, the metal lines 7 may be disposed on the surface of the charge separating layer 4.

This embodiment can also achieve the same effects as in the first embodiment described above.

### Fourth Embodiment

As shown in FIG. 6, a photoelectric transducer 16D of this embodiment is the same as the first embodiment, but concave lenses 19 instead of the convex lenses 8 are disposed at the surface of the transparent substrate 6.

The arrangement of the concave lenses 19 is almost the same as that of the convex lenses 8. The convex lenses 8 converge light, while the concave lenses 19 diverge light. The incident light 15 passing through the concave lenses 19 can also reach the adjacent openings 20 by the divergent effect. Although there is a reflection at the metal lines 7, a satisfactory amount of incident light is achieved.

The conditions of, for example, position, size, shape, material, and the number of the convex lenses 8 are not limited to the above, but may be changed as desired.

This embodiment can also achieve the same effects as in the first embodiment described above.

### Fifth Embodiment

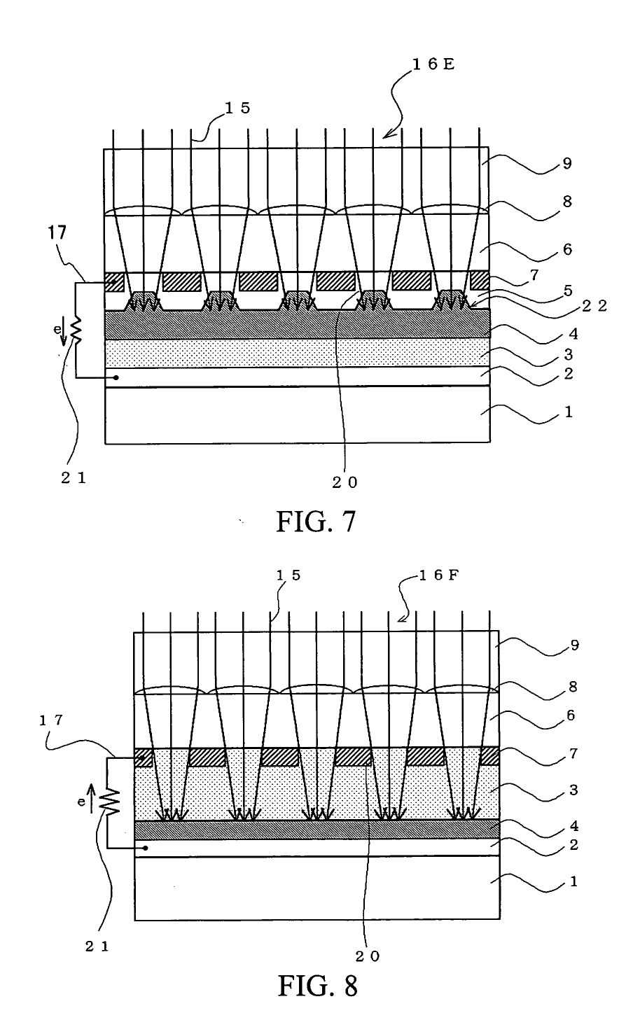

As shown in FIG. 7, a photoelectric transducer 16E is the same as in the first embodiment, but the transparent conductive layer 5 is provided in the form of projections and depressions between the metal lines 7 and the charge separating layer 4. The charge separating layer 4 has projections 22 directly below the respective openings 20. The projections 22 are close to the metal lines 7.

In this embodiment, the incident light 15 passing through the openings 20 between the metal lines 7 is incident on the charge separating layer 4 through the transparent conductive layer 5. Electrons generated in the charge separating layer 4 flow into the metal lines 7 through the transparent conductive layer 5.

Since each of the projections 22 of the charge separating layer 4 is close to the metal lines 7, the thickness of the transparent conductive layer 5 in the vicinity of each projection 22 is reduced. In addition, the contact area of the transparent conductive layer 5 and the charge separating layer 4 is enlarged by the projections 22. Consequently, electrons are generated satisfactorily and readily move from the charge separating layer 4 to the metal lines 7 through the relatively short distance of the transparent conductive layer 5. As a result, charge mobility and charge separation efficiency are improved.

Since the transparent conductive layer 5 is deposited after the metal lines 7 are formed by patterning a material layer for the metal lines on the transparent substrate 6 by reactive ion etching or ion milling, the transparent conductive layer 5 is not damaged by the patterning of the metal lines 7. The etching process for forming the metal lines 7 is suitable for finer patterning with high precision compared with wet etching.

This embodiment can also achieve the same effects as in the first embodiment described above.

### Sixth Embodiment

As shown in FIG. 8, a photoelectric transducer 16F is the same as in first embodiment, but the transparent conductive layer 5 is omitted, and the metal lines 7 are disposed at a surface of the electrolytic layer 3. The charge separating layer 4 is disposed between the conductive layer 2 and the electrolytic layer 3.

In this embodiment, the omission of the transparent conductive layer 5 does not cause conductor loss in the transparent conductive layer 5 and energy loss caused by the light absorption of the transparent conductive layer 5. In addition, almost all incident light 15 can enter the charge separating layer 4 by the convergent effect of the convex lens 8. Therefore, high photoelectric-conversion efficiency can be achieved.

Electrons generated in the charge separating layer 4 move from the conductive layer 2 functioning as an anode to the metal lines 7 functioning as cathodes. Then, iodine is reduced in the electrolytic layer 3, and the generated iodide ions provide electrons for holes in the charge separating layer 4.

This embodiment can also achieve the same effects as in the first embodiment described above.

### Seventh Embodiment

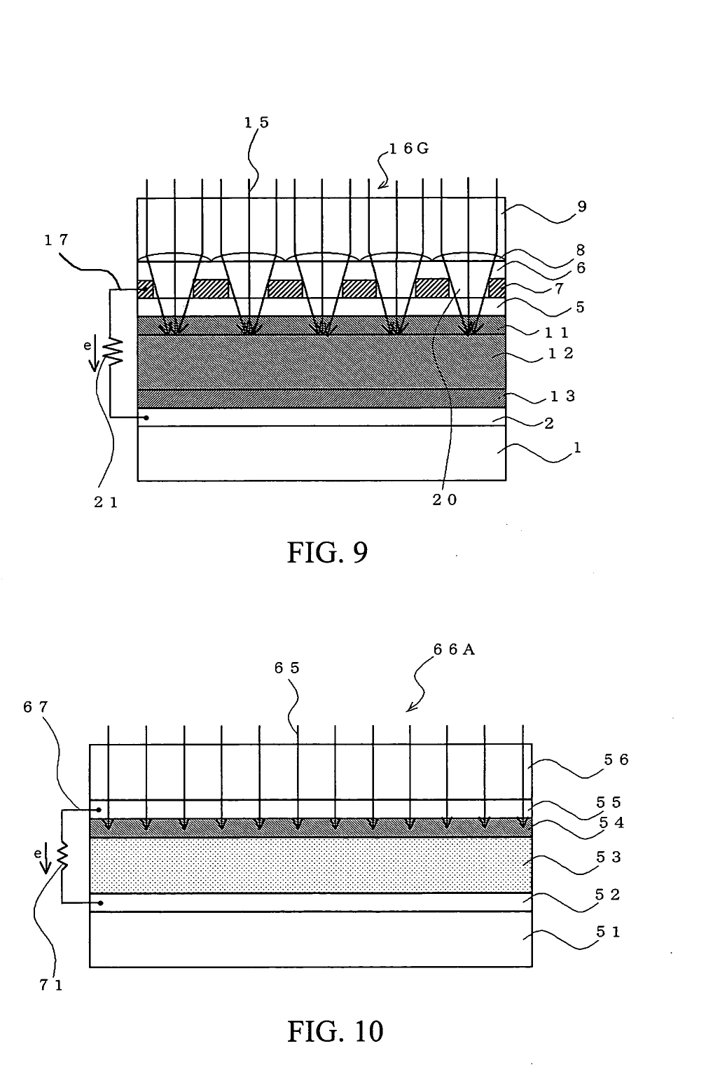

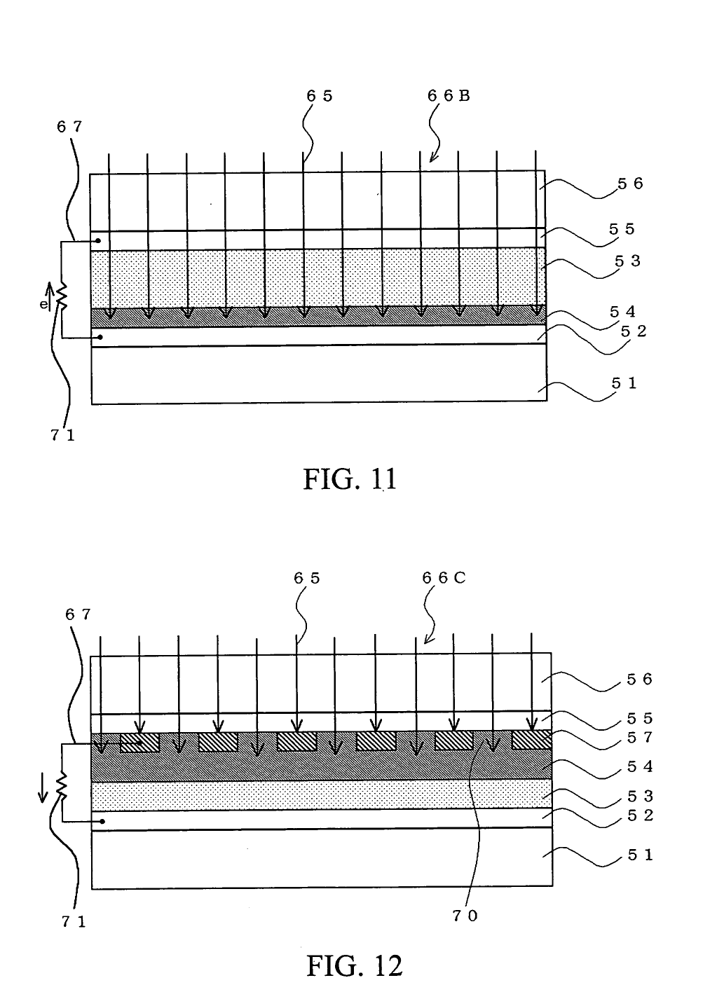

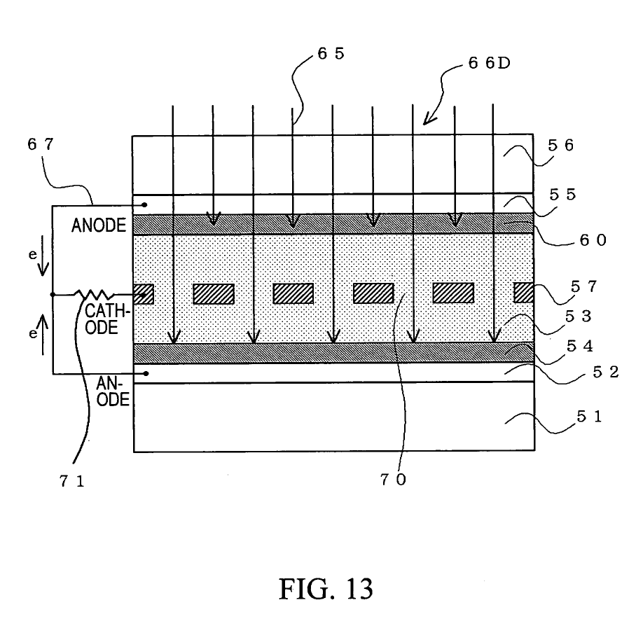

As shown in FIG. 9, a photoelectric transducer 16G is the same as in the first embodiment, but the metal lines 7 are disposed on the transparent conductive layer 5, and a photoelectric conversion layer, which functions as a solar cell composed of amorphous-silicon (a-Si) (hereinafter, referred to as “dry a-Si solar cell”) having a p-1-n junction, i.e., composed of an n-type a-Si sublayer 11, an intrinsic a-Si sublayer 12, and a p-type a-Si sublayer 13 between the transparent conductive layer 5 and the conductive layer 2.

In this embodiment, electrons generated in the photoelectric conversion layer having a p-i-n junction composed of amorphous silicon readily pass through the transparent conductive layer 5 and then can flow into the metal lines 7 because of the presence of the transparent conductive layer 5 between the n-type a-Si sublayer 11 and the metal lines 7. Furthermore, almost all the incident light 15 can be brought into the photoelectric conversion layer by the convergent effect of the convex lens 8. Therefore, high photoelectric conversion efficiency can be achieved, and conductor loss can be significantly reduced by the metal lines 7.

For example, the constituents and the thicknesses of the n-type a-Si sublayer 11, the intrinsic a-Si sublayer 12, and the p-type a-Si sublayer 13 may be set as desired.

This embodiment can also achieve the same effects as in the first embodiment described above.

The above-described embodiments can be modified based on the technical idea of the present invention.

For example, a liquid crystal lens functioning as a light-guiding means may be used in place of the on-chip lens. In the above-described photoelectric transducer, a wet photoelectric transducer or a dry photoelectric transducer is used alone. However, a wet device and a dry device may be used in combination. For example, wet devices and dry devices may be alternately disposed in the in-plane direction. Alternatively, multiple structures in which the dry device is disposed below the wet device may be used.

As described above, according to the present invention, by providing the low-resistance region in the second electrode that is in contact with the charge-separating means, electrons generated by photoelectric conversion in the charge-separating means move to the external circuit through the low-resistance region; hence, conductor loss can be reduced, and a low-loss path for the transfer of electrons can be ensured.

Since the incident light is led to the transparent portion provided in the low-resistance region by the light-guiding means and then is led to the charge-separating means, the path of the incident light can be controlled such that at least the major portion of the incident light is incident on the charge-separating means. The loss of incident light caused by the reflection of the incident light from a region other than the transparent portion can be prevented; therefore, the incident light can efficiently enter the charge-separating means. Even when a light-absorbing layer such as a transparent conductive layer is present in the second electrode, the light-guiding means reduces the amount of light that is incident on the light absorbing layer, thus reducing the amount of light absorption. Since such a path of incident light can be achieved even when the transparent portion is reduced in width, the area of the low-resistance region can be enlarged to such a degree that the low-resistance region does not interfere with the path of incident light. As a result, generated electrons readily flow into the low-resistance region, and the conductivity of the electrode is increased. Consequently, both the conductor loss and the loss of light energy can be further suppressed.

The relatively simple structure formed merely by providing the light-guiding means in addition to the first electrode, the second electrode, and the charge-separating means can reduce the conductor loss and the loss of light energy.

1. A photoelectric transducer comprising: a first electrode; a charge-separating means in contact with the first electrode; a second electrode in contact with the charge-separating means; and a light-guiding means for guiding incident light to a transparent portion provided in a low-resistance region of the second electrode and guiding the incident light to the charge-separating means.

2. The photoelectric transducer according to claim 1, wherein the charge-separating means comprises an electrolytic layer and a charge separating layer in contact with the electrolytic layer.

3. The photoelectric transducer according to claim 2, wherein the charge separating layer comprises a semiconductor sublayer containing a sensitizing dye.

4. The photoelectric transducer according to claim 1, wherein the charge-separating means comprises a junction including p-type and n-type semiconductors.

5. The photoelectric transducer according to claim 1, wherein the light-guiding means is a convex or concave on-chip lens provided above the transparent portion.

6. The photoelectric transducer according to claim 5, wherein the on-chip lens comprises an organic material that transmits light.

7. The photoelectric transducer according to claim 1, wherein the light-guiding means is a lens array disposed above the transparent portion.

8. The photoelectric transducer according to claim 5, wherein a boundary region between adjacent on-chip lenses is disposed above the second electrode.

9. The photoelectric transducer according to claim 1, wherein the second electrode comprises metal lines having a predetermined pattern and a transparent conductive layer that is in contact with the metal lines, wherein the metal lines and/or the transparent conductive layer is in contact with the charge-separating means.

10. The photoelectric transducer according to claim 9, wherein the metal lines or the transparent conductive layer is disposed adjacent to the charge-separating means.

11. The photoelectric transducer according to claim 1, wherein the second electrode comprises metal lines having a predetermined pattern, the metal lines being in contact with the charge-separating means.

12. The photoelectric transducer according to claim 11, wherein the metal lines are in contact with the charge separating layer or the electrolytic layer.
